(19) United States
(12) Patent Application Publication
(10) Pub. No.: US 2006/0250045 A1
(43) Pub. Date: Nov. 9, 2006

(54) Semimanufacture intended to be mounted on a vibrating wall or a vibrating panel for actively damping vibrations of the wall, wall or panel provided with such a semimanufacture,system provided with a semimanufacture and a control unit, wall or panel provided with a control unit and method for damping audible vibrations of a wall or panel

(76) Inventors: Marius Pieter de Goeje, Delft (NL); Michiel Wilbert Rombout Maria van Overbeek, Dordrecht (NL); Adri van der Waal, Zaltbommel (NL); Arthur Perry Berkhoff, Doetinchem (NL); Peter Jacobus Nederveen, Rotterdam (NL)

Correspondence Address: HOFFMANN & BARON, LLP, 6900 JERICHO TURNPIKE, SYOSSET, NY, 11791, US

(21) Appl. No.: 10/557,318

(22) PCT Filed: May 28, 2004
(86) PCT No.: PCT/NL04/00385

§ 371 Date: Nov. 18, 2005

(30) Foreign Application Priority Data
May 28, 2003 (NL) 1023559

(51) Int. Cl. H01L 41/00

(52) U.S. Cl. 310/311

(57) ABSTRACT

A semimanufacture intended to be mounted on a vibrating wall or a vibrating panel for actively damping the vibrations in the wall or the panel with frequencies which are at least partly audible, wherein the semimanufacture is provided with a plate wherein the plate is integrated with: at least one vibration source for generating vibrations which, in use, damp the vibrations of the wall or the panel, at least one vibration sensor for detecting the vibrations in the wall or in the panel and wiring for connecting the vibration source and/or the vibration sensor with a control unit for processing signals coming from the at least one vibration sensor and for controlling the at least one vibration source.

The invention relates to a semimanufacture intended to be mounted on a vibrating wall or a vibrating panel for actively damping the vibrations in the wall or the panel with frequencies which are at least partly audible.

The invention also relates to a wall or panel on which such a semimanufacture has been provided. The invention further relates to a system provided with a semimanufacture and a control unit.

The invention further relates to a system provided with such a wall or such a panel and a control unit.

The invention further relates to a method for damping vibrations with frequencies which are audible of a wall or panel.

It is known to use antisound for damping sound. This means that a sound wave is generated with a phase opposite to that of the original sound wave so that, as a result, a reduction of the sound level is achieved. The most obvious method to detect and to generate waves is the method in which use is made of a microphone and a loudspeaker. However, these systems are vulnerable.

In order to meet this problem, systems have been developed in which the vibration source itself is dealt with. Here, piezo elements in the form of thin slices are used which are glued directly on a vibrating wall or a vibrating panel and are then activated such that the vibrations of the wall or the panel are prevented. A drawback of this known method is that it is very laborious to provide all these fragile piezo elements one by one on the wall or the panel. It is also laborious to provide the required wirings. Particularly for larger panels and/or walls, this will be a complicated and costly business.

It is the object of the invention to provide a solution which meets the problem mentioned.

To this end, the semimanufacture according to the invention is characterized in that the semimanufacture is provided with a plate, the plate being integrated with: at least one vibration source for generating vibrations which, in use, damp the vibrations of the wall or the panel, at lo least one vibration sensor for, detecting the vibrations in the wall or in the panel-and wiring for connecting the vibration source and/or the vibration sensor with a control unit for processing signals coming from the at least one vibration sensor and for controlling the at least one vibration source.

The semimanufacture according to the invention has the advantage that it can be provided directly on the wall or on the panel. When the semimanufacture itself has been provided, this means that, also, the at least one vibration source, the at least one vibration sensor and the wiring for connecting the vibration source and vibration sensor with the control unit have been provided. The provision of the semimanufacture itself involves a relatively simple operation.

Preferably, the at least one vibration source comprises a piezo element. Preferably, further, the at least one vibration source comprises a piezo material layer with, on both sides, an electrically conductive layer, which are each connected with the wiring of the semimanufacture.

In particular, further, the at least one vibration sensor comprises a piezo element, chip or a strain gauge.

Further, in particular, the at least one vibration sensor comprises a piezo material layer with, on both sides, an electrically conductive layer, which are each connected with the wiring of the semimanufacture.

In particular, further, the plate is provided with an insulating plate such as a glass fiber/epoxy plate which is, on at least one side, at least partly, covered with a layer of copper, the wiring being, at least partly, formed from the layer of copper. However, this plate does not necessarily need to be a glass fiber/epoxy plate, but may also be a different type of “Printed Circuit Board”. Though glass fiber/epoxy is used most often, the old-fashioned Pertinax, for instance, would also be adequate.

According to a very advanced embodiment, also, at least a part of the control unit is integrated with the plate. The part of the control unit lo integrated with the plate is particularly designed in the form of at least one chip. So, the control unit may comprise at least one chip provided on the plate.

The invention also relates to a system provided with a semimanufacture according to the invention and a control unit connected with the wiring, the at least one vibration sensor and the at least one vibration source, with the control unit being arranged to detect, in use, via the at least one vibration senisor, vibrations of a wall or panel on which the semimanufacture has been mounted and to control the at least one vibration source such that the vibrations of the wall or the panel are damped.

The invention further relates to a system provided with a wall or panel according to the invention and a control unit which is connected with the wiring, the at least one vibration sensor and the at least one vibration source, the control unit being arranged to detect, in use, via the at least one vibration sensor, vibrations of the wall or panel and to control the at least one vibration source such that the vibrations of the wall or the panel are damped.

The invention further relates to a method for damping audible vibrations of the wall or panel, which method is characterized in that, on the wall or the panel, a semimanufacture is provided according to the invention and, where, with the aid of the at least one vibration sensor, vibrations of the wall or the panel are detected and where, on the basis of the detected vibrations, the at least one vibration source is controlled such that audible vibrations of the wall or the panel are damped.

The invention will now be further elucidated with reference to the drawing, in which:

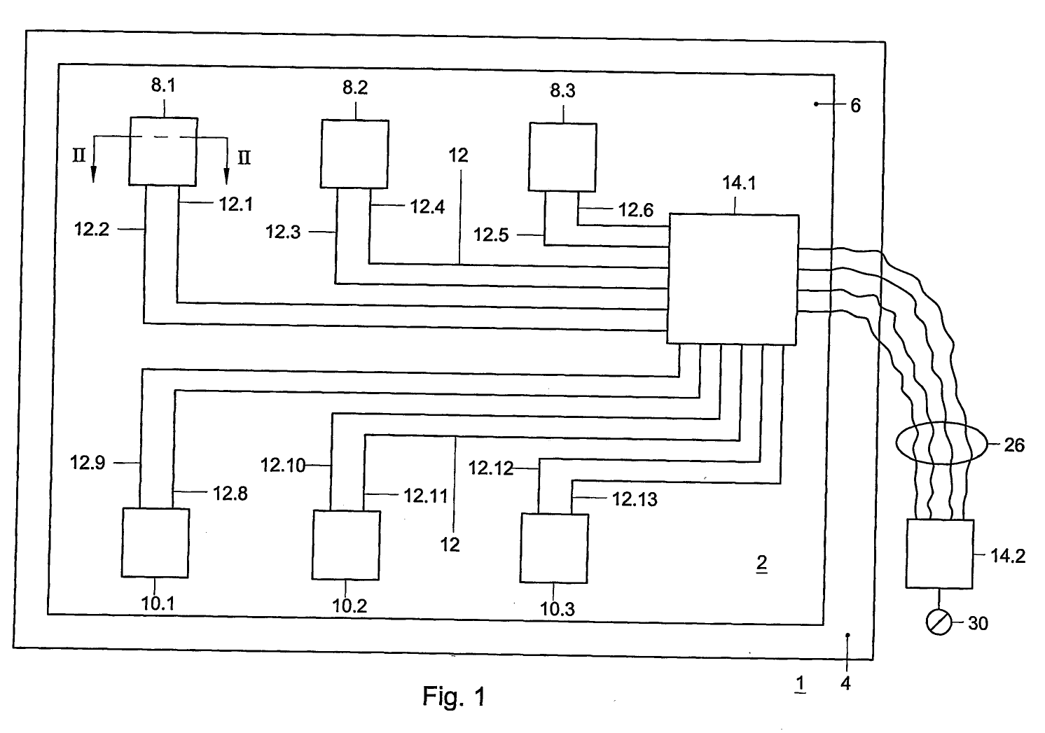

FIG. 1 shows a system according to the invention provided with a wall or panel according to the invention, a semimanufacture according to the invention being mounted on the wall or the panel, and a control unit for controlling the semimanufacture;

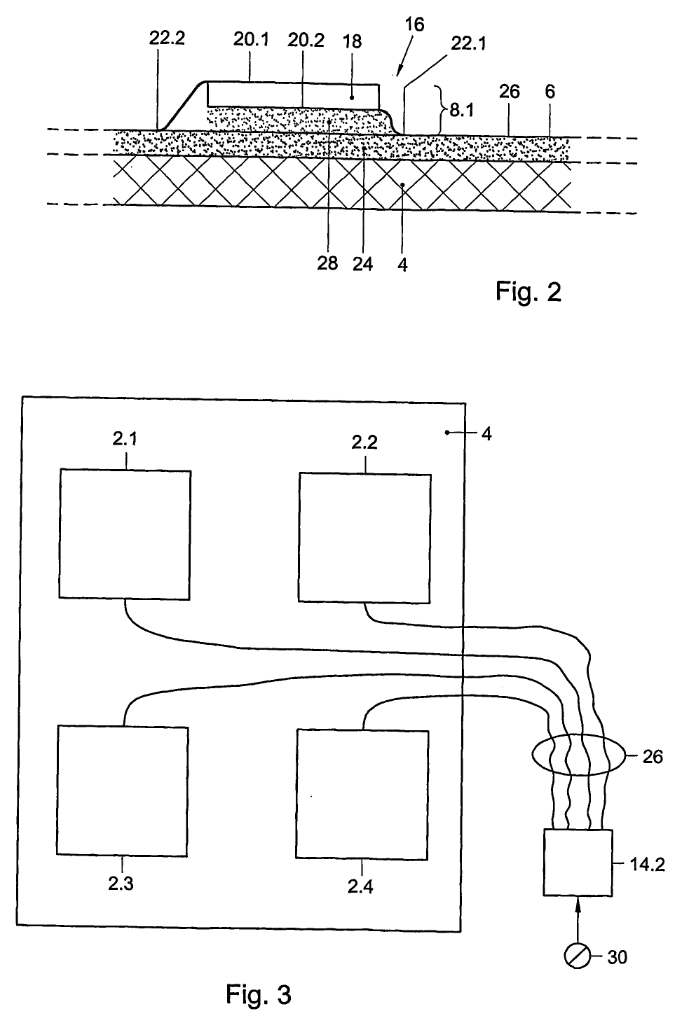

FIG. 2 shows a cross section according to the line II-II of FIG. 1; and

FIG. 3 shows a wall or panel according to the invention provided with a plurality of semimanufactures according to the invention and a control unit connected with the semimanufactures.

In FIG. 1, reference numeral 1 designates a system according to the invention. The system 1 is provided with a semimanufacture 2 intended to be provided on a vibrating wall or on a vibrating panel 4 for actively damping the vibrations in the all or the panel which are at least partly audible, that is, with frequencies which are audible. Hereinafter, the wall 4 or the panel 4 will be referred to as panel 4. The panel 4 may, for instance, be part of an inner, wall of a cabin of a vehicle such as an airplane. In use, this panel will vibrate at frequencies which are in the audible sound spectrum. Here, in effect, the panel 4 functions as a “loudspeaker”. Now, the semimanufacture 2 has been arranged to actively damp the vibrations, at least a part of the vibrations which are audible. This is achieved in that the semimanufacture 2 generates vibrations which are in antiphase with the vibrations of the panel which are to be damped.

To this end, the semimanufacture 2 is provided with a plate 6, with at least one vibration source for generating vibrations which, in use, damp vibrations of the wall or the panel being integrated with the plate. In this example, the plate 6 is provided with three vibration sources 8.1-8.3 (i=1,2,3). Further, at least one vibration sensor 10.j is integrated with the plate for detecting vibrations in the panel 4. In this example, the semimanufacture is provided with three vibration sensors 10.j (j=1,2,3). Further, the wiring 12 is integrated with the plate 6 for connecting the vibration sources and the vibration sensors with a control unit 14.1, 14.2 for processing the signals coming from the at least one vibration sensor 10.j and for controlling the at least one vibration source 8.i; all this such that the vibration source generates vibrations which, in use, damp the vibrations of the wall or the panel.

In this example, each vibration source 8.i comprises a piezo element 16. This piezo element 16 comprises piezo material layer 18 with, on both sides, an electrically conductive layer 20.1 and 20.2 respectively. The electrically conductive layer 20.2 located on a side of the piezo element 16 facing the plate 6 covers the piezo layer 18 and extends beyond the piezo layer 18, and is connected with a part of the wiring 12 near an end 22.1 of a part of the electrically conductive layer 20.2 extending beyond the piezo layer. The electrically conductive layer 20.1 located on a side of the piezo layer 18 facing opposite to where the electrically conductive layer 20.2 is located also covers the piezo layer 18 and also extends on one side of the piezo layer beyond the piezo layer 18. A free end of the part extending beyond the piezo layer 18, which end has reference numeral 22.2, is also connected with a part of the wiring 12.

In this example, the plate 6 is provided with an insulating plate 24 such as a glass fiber/epoxy plate 24 which is, on at least one side 26, at least partly, covered with a layer of copper. However, other insulating materials are also possible, such as Pertinax and the like. This layer of copper has, at least partly, been etched away, the remaining layer of copper forming the wiring 12 in this example. In this example, the wiring 12 comprises a track 12.1 connecting the end 22.1 with the control unit 14 and a track 12.2 connecting the end 22.2 with the control unit 14.

In this example, the ends 22.1 and 22.2 are connected with the tracks 12.1 and 12.2 with the aid of electrically conductive glue.

The configuration of the vibration sources 8.2 and 8.3 is identical to that of the vibration source 8.1. The vibration sources 8.2 and 8.3 are also connected with the control unit 14 by means of the respective tracks 12.3-12.6.

The vibration sensors 10.1-10.3 are identical to the vibration sources 8.1-8.3. Thus, the vibration sensor 10.1 also consists of a piezo element comprising a piezo material layer with, on both sides, an electrically conductive layer, which are each connected with the wiring of the semimanufacture. Here, also, for instance, a free end of an electrically conductive layer 20.2 of the vibration sensor 10.1 is connected with a track 12.8 and an end 22.2 of the electrically conductive layer 20.2 of the vibration sensor 10.1 is connected with a track 12.9, with the tracks 12.8 and 12.9 being connected with the control unit 14. Completely analogously, the vibration sensors 10.2 and 10.3 are connected with the control unit 14 by means of the tracks 12.10-12.13.

In this example, further, for instance, the vibration source 8.1 has been glued on the plate 6 by means of glue 24. In this manner, in the sense of the patent, the vibration source 8. Is integrated with the plate 6. Completely analogously, the vibration sources 8.2 and 8.3 and the vibration sensors 10.1-10.3 have been glued on the plate 6 with the aid of glue.

In this example, the control unit comprises a first control subunit 14.1 and a second control subunit 14.2. The tracks 12.1-12.13 are connected with the first control subunit 14.1. The first control subunit 14.1 is also integrated with the plate. In this example, the first control subunit 14.1 comprises at least one chip provided on the plate 6. The second control subunit 14.2 is connected with the first control subunit 14.1 by means of a wiring 26. The second control subunit 14.2 comprises inter alia a supply source which provides the first control subunit 14.1 with energy. In this example, the first control subunit 14.1 is arranged to process a signal coming from the vibration sensor 10.1, which signal represents a vibration of the panel 4 detected by the vibration sensor 10.1 and to then control, on the basis of the detected signal, the vibration source 8.1 such that it generates vibrations, such that the vibrations of the panel 4 are damped by the generated vibrations. Completely analogously, in this example, the vibration source 8.2 is controlled on the basis of signals which have been detected with the aid of the vibration sensor 10.2. Further, the vibration source 8.3 is controlled on the basis of signals coming from the vibration sensor 10.3. However, this is not essential to the invention. For instance, it is also possible that the signals coming from the vibration sensors 10.1-10.3 are processed in combination for controlling the vibration sources 8.1, 8.2 and 8.3 on an individual or on a joint basis.

In this example, the semimanufacture 2 has been mounted on the panel 4 with the aid of glue 24. Other attachment means are also possible. It is, for instance, also possible to mount the semimanufacture 2 on the wall or the panel 4 by means of an adhesive film 24.

An advantage of the, semimanufacture 2 is that it can easily be mounted on the panel 4 or the wall 4. Thus, it is not required that the vibration sensors 10.j and the vibration sources 8.i as well as the wiring 12 are to be mounted on the panel 4 or the wall 4 on an individual basis. Instead, the whole semimanufacture in which the wiring, the vibration sensors and the vibration sources are integrated can be mounted all at once in a simple manner on the panel 4 or the wall 4, for instance with the aid the glue or adhesive film mentioned.

The invention is by no means limited to the above-described embodiment. It is, for instance, possible that the electrically conductive layer 20.2 of a vibration source 8.i or a vibration sensor 10.j is formed by a part of the copper layer 26 of the plate 6, which copper layer also forms at least a part of the wiring 12. It is also possible that the free end 22.1, for instance of the vibration source 8.1, is connected with the track 12.1 with a same glue as the glue 28 by means of which the vibration source 8.1 is connected with the plate 6. In particular, the plate 6 is manufactured from a flexible material so that the plate 6 can be mounted on the wall or the panel in a simple manner, also when the wall or panel 4 has a curved design. The plate 6 may, for instance, have a thickness (excluding the vibration sensors 8.i and the vibration sources 10.j) of 0.1 mm-5 mm. If the wall or the panel 4 which is provided with the semimanufacture 2 is used as a part of an inner wall of a cabin of a vehicle, such as for instance an airplane, the semimanufacture is preferably provided between the inner wall and an outside of the vehicle. However, it is also possible for the semimanufacture to be provided on an inside of the vehicle on the inner wall of a cabin, which inside is, for instance, lined with cloth which also covers the semimanufacture.

It is also possible (see FIG. 3) that a panel or wall 4 is provided with a plurality of semimanufactures 2.k (in this example k=1,2,3,4). In this example, each semimanufacture 2.k has a same configuration as the semimanufacture 2 according to FIG. 1. Each semimanufacture 2.k is therefore provided with a control subunit 14.1. Each control subunit 14.1 is connected with a second control subunit 14.2 via the wiring 26. In this example, the system shown in FIG. 3 also comprises a microphone 30 connected with the second control subunit 14.2. In this example, the microphone 30 receives sound in the proximity of the panel 4. This may, for instance, be sound in the cabin of a vehicle. This sound is supplied to each of the control subunits 14.1 via the second control subunit 14.2 and the wiring 26. The sound can be used to make a first rough estimate of what frequencies are emitted by the panel or the wall 4 and are therefore to be damped. On the basis of this first rough estimate, the vibration sources of the semimanufactures 2.k can be controlled for a first rough damping of the vibrations of the panel or the wall 4. Then, the control subunits 14.1 can tune the vibrations of the vibration sources 8.i in a feedback control loop known per se (frequency and phase are adjusted), so that the damping is optimal on the basis of the vibrations of the panel 4 detected by the vibration sensors 10.j of the respective semimanufacture.

Completely analogously, in FIG. 1, another microphone 30 may be used which is connected with the second control subunit 14.2. The second control subunit 14.2 sends information about the frequency of the vibrations received by the microphone 30 via the wiring 26 to the first control subunit 14.1. The first control subunit 14.1 uses these signals as a first rough estimate for the frequency at which the vibration sources 8.i can be controlled. Then, a fine-tuning takes place of the vibrations of the vibration sources 8.i (frequency and phase are adjusted) on the basis of vibrations observed by the vibration sensors 10.j. The semimanufactures 2.k may have standardized dimensions so that a wall or panel can be lined therewith in a modular manner. Thus, a semimanufacture may have dimensions of, for instance, 50×100 cm. Different dimensions such as 50×50 cm or 100×100 cm may also be used. Instead of a piezo element, the vibration sensor may also comprise other vibration sensors such as a chip or a strain gauge. However, the plate 6 does not necessarily need to be a glass fiber/epoxy plate, but may also be a different type of “Printed Circuit Board” (PCB). Though glass fiber/epoxy is used most often, the old-fashioned Pertinax, for instance, would also be adequate. Such variants are each understood to be within the scope of the invention.

1. A semimanufacture intended to be mounted on a vibrating wall or a vibrating panel for actively damping the vibrations in the wall or the panel with frequencies which are at least partly audible, characterized in that the semimanufacture is provided with a plate wherein the plate is integrated with: at least one vibration source for generating vibrations which, in use, damp the vibrations of the wall or the panel, at least one vibration sensor for detecting the vibrations in the wall or in the panel and wiring for connecting the vibration source and/or the vibration sensor with a control unit for processing signals coming from the at least one vibration sensor and for controlling the at least one vibration source.

2. A semimanufacture according to claim 1, characterized in that the at least one vibration source comprises a piezo element.

3. A semimanufacture according to claim 2, characterized in that the at least one vibration source comprises a piezo material layer with, on both sides, an electrically conductive layer which are each connected with the wiring of the semimanufacture.

4. A semimanufacture according to claim 1, characterized in that the at least one vibration sensor comprises a piezo element, chip or strain gauge.

5. A semimanufacture according to claim 4, characterized in that the at least one vibration sensor comprises a piezo material layer with, on both sides, an electrically conductive layer which are each connected with the wiring of the semimanufacture.

6. A semimanufacture according to claim 1, characterized in that the plate is provided with an insulating plate such as a glass fiber/epoxy plate which is, on at least one side, at least partly covered with a layer of copper, wherein the wiring is at least partly formed from the layer of copper.

7. A semimanufacture according to claim 2, characterized in that the at least one vibration source is provided on the glass fiber/epoxy plate.

8. A semimanufacture according to claim 3, characterized in that one of the electrically conductive layers of the at least one vibration source is connected with a part of the wiring formed by the layer of copper, for instance with an electrically conductive glue.

9. A semimanufacture according to claim 3, characterized in that one of the electrically conductive layers of the at least one vibration source is formed by a part of the layer of copper.

10. A semimanufacture according to claim 4, characterized in that the at least one vibration sensor is provided on the insulating plate.

11. A semimanufacture according to claim 5, characterized in that one of the electrically conductive layers of the at least one vibration sensor is connected with a part of the wiring formed by the layer of copper, for instance with an electrically conductive glue.

12. A semimanufacture according to claim 5, characterized in that one of the electrically conductive layers of the at least one vibration sensor is formed by a part of the layer of copper.

13. A semimanufacture according to claim 1, characterized in that at least a part of the control unit is also integrated with the plate.

14. A semimanufacture according to claim 13, characterized in that the control unit comprises at least one chip provided on the plate.

15. A semimanufacture according to claim 1, characterized in that the plate of the semimanufacture has a flexible design.

16. A wall or panel which can be set vibrating, wherein, on the wall or the panel, at least one semimanufacture according to claim 1 is mounted for damping the vibrations of the wall or the panel.

17. A wall or panel according to claim 16, characterized in that the semimanufacture is mounted on the wall or the panel by means of glue.

18. A wall or panel according to claim 17, characterized in that the semimanufacture is mounted on the wall or the panel by means of an adhesive film.

19. A wall or panel according to claim 17, characterized in that the wall or the panel is part of an inner wall of a cabin or a vehicle such as an airplane.

20. A wall or panel according to claim 19, characterized in that the semimanufacture is located between the inner wall and an outside of the vehicle.

21. A wall or panel according to claim 16, characterized in that a plurality of semimanufactures are provided on the wall or the panel.

22. A system provided with a semimanufacture according to claim 1 and a control unit which is connected with the wiring, the at least one vibration sensor and the at least one vibration source, wherein the control unit is arranged to detect, in use, via the at least one vibration sensor, vibrations of a wall or panel on which the semimanufacture has been mounted and to control the at least one vibration source such that the vibrations of the wall or the panel are damped.

23. A system provided with a wall or panel according to claim 16 and a control unit which is connected with the wiring, the at least one vibration sensor and the at least one vibration source, wherein the control unit is arranged to detect, in use, via the at least one vibration sensor, vibrations of the wall or the panel and to control the at least one vibration source such that the vibrations of the wall or the panel are damped.

24. A method for damping vibrations with frequencies which are audible of a wall or panel, characterized in that, on the wall or the panel, a semimanufacture is provided according to claim 1, and wherein, with the aid of the at least one vibration sensor, vibrations of the wall or the panel are detected and wherein, on the basis of the detected vibrations, the at least one vibration source is controlled such that the vibrations of the wall or the panel or damped.

25. A semimanufacture according to claim 6, characterized in that the at least one vibration source is provided on the glass fiber/epoxy plate.

26. A semimanufacture according to claim 7, characterized in that one of the electrically conductive layers of the at least one vibration source is connected with a part of the wiring formed by the layer of copper, for instance with an electrically conductive glue.

27. A semimanufacture according to claim 7, characterized in that one of the electrically conductive layers of the at least one vibration source is formed by a part of the layer of copper.

28. A semimanufacture according to claim 6, characterized in that the at least one vibration sensor is provided on the insulating plate.

29. A semimanufacture according to claim 10, characterized in that one of the electrically conductive layers of the at least one vibration sensor is connected with a part of the wiring formed by the layer of copper, for instance with an electrically conductive glue.

30. A semimanufacture according to claim 10, characterized in that one of the electrically conductive layers of the at least one vibration sensor is formed by a part of the layer of copper.
